(19) United States
(12) Patent Application Publication
(10) Pub. No.: US 2024/0235164 A9
(43) Pub. Date: Jul. 11, 2024

(54) Semiconductor Emitter

(71) Applicant: ams-OSRAM International GMBH, Regensburg (DE)

(72) Inventors: Bruno Jentzsch, Regensburg (DE); Hubert Halbritter, Dietfurt (DE); Alexander Behres, Pfatter (DE); Alvaro Gomez-lglesias, Regensburg (DE); Christian Lauer, Pettendorf (DE); Simon Baumann, Regensburg (DE)

(21) Appl. No.: 18/546,593

(22) PCT Filed: Jan. 27, 2022
(86) PCT No.: PCT/EP2022/051885

§ 371 Date: Aug. 15, 2023

(30) Foreign Application Priority Data
Feb. 24, 2021 (DE) 10 2021 104 343.3

(51) Int. Cl. H01S 5/343; H01S 5/20; H01S 5/30

(52) U.S. Cl. CPC H01S 5/343; H01S 5/2031; H01S 5/3013; H01S 5/3095

(57) ABSTRACT

In an embodiment a semiconductor emitter includes a semiconductor layer sequence having a plurality of active zones, each active zone including at least one quantum well layer and at least two barrier layers between which the at least one quantum well layer is embedded, and at least one tunnel diode located along a growth direction of the semiconductor layer sequence between adjacent active zones, wherein a thickness of the at least one tunnel diode is at most 40 nm, and wherein a distance between adjacent barrier layers of adjacent active zones, facing the at least one tunnel diode, is at most 50 nm.

### CROSS-REFERENCE TO RELATED APPLICATIONS

This patent application is a national phase filing under section 371 of PCT/EP2022/051885, filed Jan. 27, 2022, which claims the priority of German patent application 102021104343.3, filed Feb. 24, 2021, each of which is incorporated herein by reference in its entirety.

### TECHNICAL FIELD

A semiconductor emitter is specified.

### SUMMARY

Embodiments provide a semiconductor emitter that efficiently emits imagable laser radiation.

According to at least one embodiment, the semiconductor emitter comprises a semiconductor layer sequence. The semiconductor layer sequence is preferably based on a III-V compound semiconductor material. The semiconductor material is, for example, a nitride compound semiconductor material such as AlₙIn₁₋ₙ₋ₘGaₘN or a phosphide compound semiconductor material such as AlₙIn₁₋ₙ₋ₘGaₘP or also an arsenide compound semiconductor material such as AlₙIn₁₋ₙ₋ₘGaₘAs or such as AlₙGaₘIn₁₋ₙ₋ₘAsₖP₁₋ₖ or such as In₁₋ₘGaₘAsₖSb₁₋ₖ or likewise InₙGa₁₋ₙSb, where in each case 0≤n≤1, 0≤m≤1 and n+m≤1 and 0≤k<1. For example, 0<n≤0.8,

0.4≤m<1, and n+m≤0.95 as well as 0<k≤0.5 apply to at least one layer or to all layers of the semiconductor layer sequence. In this context, the semiconductor layer sequence may comprise dopants as well as additional components. For the sake of simplicity, however, only the essential constituents of the crystal lattice of the semiconductor layer sequence, that is, Al, As, Ga, In, N, P or Sb, are given, even if these may be partially replaced and/or supplemented by small amounts of additional substances.

According to at least one embodiment, the semiconductor emitter is a semiconductor laser diode, LD for short, or a superluminescent light emitting diode, SLED for short, or a light emitting diode, LED for short. Preferably, the semiconductor emitter is a semiconductor laser diode so that coherent laser radiation is generated and emitted during operation.

According to at least one embodiment, the semiconductor layer sequence includes one or more active zones. The preferably multiple active zones each include one or more quantum well layers. The at least one quantum well layer is configured in particular for the generation of laser radiation. The term quantum well has no meaning here with regard to the dimensionality of the quantization. It thus includes, among other things, structures with quantization in one, two or three spatial directions and any combination of these structures.

According to at least one embodiment, the one or more active zones each comprise one or more barrier layers, in particular at least two barrier layers each, between which the at least one quantum well layer is embedded. In particular, the barrier layers and the at least one quantum well layer directly follow each other along the growth direction. It is possible that in the active zone in question the number of barrier layers is greater by one than the number of the at least one quantum well layer.

According to at least one embodiment, a distance between adjacent barrier layers of different active zones facing the at least one tunnel diode across the associated tunnel diode is at most 50 nm or at most 30 nm or at most 10 nm. In other words, adjacent active zones are located close to each other. Thus, the barrier layers of two different adjacent active zones have a distance from each other of at most 50 nm or at most 30 nm or at most 10 nm, and/or a thickness of an intermediate region between the adjacent active zones is smaller than said distances, respectively.

The active zones are thus optically connected with each other. This means, for example, that a mode of an active zone extends into the neighboring active zones.

According to at least one embodiment, the semiconductor layer sequence comprises one or more tunnel diodes. The at least one tunnel diode is located along a growth direction of the semiconductor layer sequence between two adjacent active zones. The at least one tunnel diode may be directly adjacent to the respective active zones, for example, to barrier layers of the respective active zones.

According to at least one embodiment, a thickness of the at least one tunnel diode is at most 40 nm or at most 30 nm or at most 25 nm. Alternatively or additionally, the thickness of the at least one tunnel diode is at least 6 nm or at least 10 nm. If several of the tunnel diodes are present in the semiconductor layer sequence, all tunnel diodes may have the same structure, or the semiconductor layer sequence comprises differently structured tunnel diodes.

According to at least one embodiment, in the intended operation of the semiconductor emitter, a local intensity of an optical fundamental mode at the at least one tunnel diode is at least 35% or at least 50% or at least 60% or at least 80% or at least 90% of a maximum intensity of the fundamental mode. That is, the at least one tunnel diode is located at a position of the waveguide with a comparatively high intensity of the fundamental mode.

The term ‘fundamental mode’ refers in particular only to a vertical mode, that is, to a mode parallel to the growth direction of the semiconductor layer sequence and/or in the direction perpendicular to the active zones. The term ‘fundamental mode’ does not make any statement about horizontal modes, which run in the direction parallel to the active zones and in the direction perpendicular to a resonator, as well as about longitudinal modes, which run along the resonator.

In at least one embodiment, the semiconductor emitter comprises a semiconductor layer sequence which has:
a plurality of active zones each having at least one quantum well layer, in particular for generating laser radiation,
at least one tunnel diode which is located along a growth direction of the semiconductor layer sequence between adjacent active zones, wherein
a thickness of the at least one tunnel diode being at most 40 nm, and
in the intended operation, a local intensity of a fundamental optical mode at the at least one tunnel diode being at least 50% of a maximum intensity.

To achieve high powers in, for example, laser diodes for LiDAR applications, three separate waveguides separated from each other by means of tunnel diodes have been implemented up to now. This leads to, for example, three individual laser modes in the optical near field. This approach also requires a relatively thick epitaxially grown semiconductor layer sequence with a thickness of about 10 μm to 15 μm. These, for example, three luminescent stripes or modes optically image in the optical near field and far field accordingly. This imaging limits the étendue in particular. In view of this, it is desirable to have only one laser line with very high power density. This would, for example, avoid dark spots in the optical image and allow better collimation.

In particular, in the semiconductor emitter described here, a thinner waveguide design is used that enables high optical power densities, but without coherences between, for example, individual waveguides: For example, a thinner triple waveguide epitaxy leads to coupling of the modes of the waveguides involved. These higher order supermodes would lead to efficiency losses and coherence effects as well as interference effects, which would be visible especially in the optical far field, for example, as double peaks. In the laser design described here, on the other hand, there is preferably a single waveguide for a fundamental mode in which there are multiple active zones or pn junctions, connected by intermediate tunnel diodes, in order to achieve high optical power densities.

Thus, in particular, a supermode waveguide design with multiple stacked active quantum well structures in combination with low-absorption tunnel diodes is proposed. This leads to higher achievable power densities at smaller étendue. For example, lower manufacturing costs, a more compact design on the customer side and efficiency improvements are achievable.

In particular, the semiconductor emitter described herein is a laser, such as a horizontal cavity surface emitting laser, also referred to as HCSEL, and/or a thin film multi-stack epi, that is, a growth substrate-free epitaxial layer structure with multiple active quantum well structures stacked along a growth direction. The semiconductor emitter can be used, for example, in industrial and automotive applications, as well as in LiDAR applications or for material processing. Thus, the semiconductor emitter is in particular a thin-film laser diode with ultra-high power density, which enables a compact optical system on the customer side, and which can be manufactured with lower costs.

Compared to an alternative approach, according to which the tunnel diodes are located in the zero points of the optical field distribution, in VCSELs, for example, in the zero points in the vertical standing waves or in so-called stacked EE lasers in or near the zero point of, for example, higher order modes or as a connection between individual, independent modes, the approach followed here is purposefully different: According to the approach described here, the tunnel diodes are not located in zero points of the optical field, but within the fundamental mode.

A preferred component for this purpose are, in particular, low-absorption tunnel diodes:
One possibility is that the thickness of the tunnel diodes is approximately as small as the width of the space charge region formed by the doping, which then does not absorb or absorbs only slightly as a space charge region.
Typical thicknesses for the highly doped tunnel layers, also referred to as tunnel junctions or TJ for short, are here in the range of around 10 nm and less, both for the p-TJ and the n-TJ.
Typical tunnel diode dopants, for example, for 10 nm GaAs:Te on the n-side and ionm GaAs:C on the p-side for a 940 nm laser, are in the range of 1×10²⁰ for, for example, a C doping or in the range of 5×10¹⁹ for, for example, a Te doping.
Typical band gaps of the tunnel diode materials are preferably outside the laser wavelength, for example, approximately or at least 50 nm away from it.

The waveguide design, that is, the refractive index profile, is preferably designed in such a way that primarily the fundamental mode can be guided—that is, the thickness of the waveguide is limited, which means that the individual layers, such as the TJs and the quantum well layers, cladding layers and barrier layers, should be realized grown close together.

Further design possibilities include, for example, slightly different band gaps or numbers of quantum well layers in the individual active zones or asymmetries with respect to the arrangement and/or geometry of the waveguide and/or the TJs. For example, the tunnel diodes can achieve a relatively high refractive index in their composition and thus effectively contribute to waveguiding.

A preferred component for an efficient, for example, Gaussian-like supermode or fundamental mode is therefore the lowest possible absorption of the waveguide, in particular of the at least one tunnel diode. One idea for this is: The thinner the tunnel diode, the larger the proportion of the space charge region in relation to the total thickness. A thickness of the space charge region is about 10 nm, depending on the doping level. Since the space charge region contains no, or only a few, free charge carriers, a so-called free-carrier absorption is not very high here despite high doping. The at least one tunnel diode should therefore be as thin as possible and have a band gap not close to the laser wavelength.

Provided that the space charge region of at least one tunnel diode corresponds to a large portion of the total tunnel diode thickness, it can then be embedded in the waveguide without generating large losses. Then the waveguide is preferably designed so that only the fundamental mode oscillates. For example, the waveguide can be designed as narrow as possible. Thus, for example, one obtains an approximately 3 μm thin triple epitaxial stack of three coupled active zones with two tunnel diodes in between, which together lead a narrow supermode as the first fundamental mode due to the refractive index contrast of quantum well layers plus barriers and ramps plus tunnel diodes relative to cladding layers.

According to at least one embodiment, the active zones and the at least one tunnel diode are located in a common waveguide of the semiconductor layer sequence. In particular, the semiconductor layer sequence then has exactly two cladding layers which adjoin the exactly one waveguide. The waveguide has an increased refractive index compared to the cladding layers and the cladding layers are comparatively thick, for example, at least 0.5 μm thick or at least 0.8 μm thick and/or at most 10 μm thick or at most 3 μm thick or at most 1.3 μm thick. This does not preclude individual thin sublayers in the cladding layers from having a larger refractive index, as long as an average or effective refractive index of the cladding layers is smaller than an average or effective refractive index of the waveguide. Such partial layers have, for example, a thickness of at most 0.5 μm or of at most 0.2 μm and/or of at most 20% or of at most 5% of a total thickness of the corresponding cladding layer.

According to at least one embodiment, a thickness of the common waveguide together with the two associated cladding layers is at most 10 μm or at most 4 μm or at most 2.5 μm. For example, the common waveguide in which the at least one tunnel diode and the active zones are located has a thickness of at most 1.2 μm or of at most 0.8 μm or of at most 0.4 μm. Alternatively or additionally, the thickness of the waveguide alone is at least 0.1 μm or at least 0.2 μm.

According to at least one embodiment, one of the cladding layers or both cladding layers has a stepped profile. That is, a refractive index of the at least one cladding layer in question decreases in the direction away from the active zones with at least one step. The number of jumps or steps is, for example, between one and five inclusive. Alternatively, it is possible that the at least one relevant cladding layer exhibits, at least in places, a ramped, continuous refractive index change. The decrease in refractive index in the direction away from the waveguide may be monotonic or strictly monotonic, or the relevant cladding layer may optionally also exhibit thin, localized regions of increasing refractive index.

According to at least one embodiment, a thickness of a space charge region of the at least one tunnel diode is at least 20% or at least 30% or at least 50% or at least ⅔ of a total thickness of the at least one tunnel diode in the intended operation of the semiconductor emitter. That is, in operation, the tunnel diode may be predominantly formed by a space charge region.

According to at least one embodiment, a bandgap of the at least one tunnel diode differs by at least 10 nm or at least 30 nm or at least 50 nm from a wavelength of maximum intensity of the active zones. Alternatively or additionally, this difference is at most 0.2 μm or at most 100 nm. The band gap, which corresponds to an energy E, and the associated wavelength λ can be converted into each other via the relationship E=hc/λ, where h denotes the Planck's constant and c the speed of light. The wavelength and the speed of light refer here to the vacuum values. This energetic gap reduces absorption of radiation generated in the active zones in the at least one tunnel diode. Thus, the band gap of the at least one tunnel diode is preferably higher than a band gap energy of the active zones equivalent to the wavelength of the laser radiation.

If there are several active zones for emission of different wavelengths, the active zone with the highest band gap, that is, the smallest emission wavelength, is used to calculate the above energy gap. If there are several tunnel diodes with optionally different structures, the smallest band gap of the tunnel diodes is used to calculate the above energy gap.

According to at least one embodiment, the at least one tunnel diode is formed from two oppositely highly doped layers. In other words, the at least one tunnel diode may comprise the two oppositely highly doped layers. Highly doped means, for example, that an average dopant concentration in the at least one tunnel diode is at least 2×10¹⁹ cm⁻³ or at least 5×10¹⁹ cm⁻³ and/or at most 5×10²⁰ cm⁻³ or at most 2×10²⁰ cm⁻³ or at most 1×10²⁰ cm⁻³. In addition, these values may apply not only averaged over the tunnel diode in question, but also to each of the highly doped layers. For tunnel diodes comprising Sb, the doping may even be omitted altogether or be significantly smaller and, for example, be at least 1×10¹⁸ cm⁻³.

According to at least one embodiment, the highly doped layers each have a thickness of at least 3 nm or of at least 5 nm. Alternatively or additionally, this thickness is at most 25 nm or at most 20 nm or at most 15 nm.

According to at least one embodiment, the at least one tunnel diode is composed of the two oppositely highly doped layers and at least one intermediate layer in between. That is, the at least one tunnel diode may, for example, consist of three layers. Preferably, the same applies to the thickness of the intermediate layer as to the thicknesses of the highly doped layers. The intermediate layer may be p-doped or n-doped. For example, a dopant concentration in the intermediate layer is smaller than in the adjacent highly doped layers, in particular smaller by at least a factor of 1.5 or by at least a factor of 2 and/or by at most a factor of 10 or by at most a factor of 5.

According to at least one embodiment, the semiconductor layer sequence further comprises at least one transition layer. Preferably, the transition layer is lowly doped. A dopant concentration of the transition layer is, for example, at most 1×10¹⁷ cm⁻³ or at most 3×10¹⁶ cm⁻³ and/or at least 1×10¹⁵ cm⁻³ or at least 5×10¹⁵ cm⁻³. The transition layer adjoins the at least one tunnel diode, in particular directly. It is possible that there is a transition layer on both sides of the tunnel diode or on both sides of each of the tunnel diodes. For example, the p-side transition layers are thinner than the n-side transition layers, so that the transition layers can be asymmetrically shaped around the associated tunnel diode. Alternatively, the transition layers may have the same thickness and thus be symmetrical around the associated tunnel diode. A thickness of the at least one transition layer is, for example, at least 5 nm or at least 10 nm and/or at most 50 nm or at most 30 nm. By means of such transition layers, in particular an improvement of a charge carrier transport is achievable.

According to at least one embodiment, the at least one transition layer has a ramp-shaped refractive index profile. Preferably, the refractive index increases in the direction towards the associated tunnel diode.

According to at least one embodiment, the at least one tunnel diode is made of GaAs and/or of InGaAs or comprises GaAs and/or InGaAs and optionally also AlGaAs. This applies in particular to semiconductor emitters with an emission wavelength in the range of 0.7 μm to 1.3 μm. In this case, the optional transition layer is made of AlGaAs, for example, with the Al content preferably decreasing to zero towards the tunnel diode.

According to at least one embodiment, the at least one tunnel diode is made of InP and InGaAs or comprises InP and InGaAs and optionally also AlGaAs. This applies in particular to semiconductor emitters with an emission wavelength in the range of 1.3 μm to 2.0 μm.

According to at least one embodiment, the at least one tunnel diode is made of InAsSb and GaSb or comprises InAsSb and GaSb. This applies in particular to semiconductor emitters with an emission wavelength in the range of 2.0 μm to 5 μm.

According to at least one embodiment, the at least one tunnel diode is made of InGaN or comprises InGaN or also AlInGaN or AlGaN. This applies in particular to semiconductor emitters with an emission wavelength in the range of 0.3 μm to 0.6 μm.

According to at least one embodiment, a dopant concentration of layers of the semiconductor layer sequence adjacent to the at least one tunnel diode is smaller than the average dopant concentration in the at least one tunnel diode by at least a factor of three or by at least a factor of ten or by at least a factor of 100. The adjacent layers are, for example, barrier layers of the active zones or the transition layers.

According to at least one embodiment, the optical fundamental mode has multiple local maxima and one or more local minima. This is achievable, for example, by a refractive index variation within the waveguide. The at least one local minimum is located between two adjacent local maxima. The local maxima may include an absolute maximum.

According to at least one embodiment, the active zones are arranged in or near the local maxima and/or the at least one tunnel diode is arranged in or near the at least one local minimum. If several tunnel diodes and several local minima are present, preferably one tunnel diode each is arranged in or close to a local minimum. The local minima may be comparatively weak and may, for example, have at least 80% or 90% of an intensity of the adjacent local maxima. Close to the local minimum means, for example, that a distance of the relevant tunnel diode to the associated local minimum is at most 30% or at most 10% of a largest distance of this local minimum to the adjacent maxima.

According to at least one embodiment, at least two of the active zones are configured to generate radiation of different wavelengths. For example, maximum intensity wavelengths of the active zones differ from each other by at least 5 nm or by at least 10 nm and/or by at most 40 nm or by at most 20 nm. Alternatively, all active zones can be configured to generate radiation of the same nominal wavelength of maximum intensity.

According to at least one embodiment, the semiconductor layer sequence includes at least three or at least four of the active zones and/or at most ten or at most five of the active zones. It is possible that each of the active zones includes between two and ten, inclusive, or between three and six, inclusive, of the quantum well layers. Alternatively, the active zones or one of the active zones or some of the active zones have only one quantum well layer.

### BRIEF DESCRIPTION OF THE DRAWINGS

In the following, a semiconductor emitter described here is explained in more detail with reference to the drawing on the basis of exemplary embodiments. Identical reference signs indicate identical elements in the individual figures. However, no references to scale are shown; rather, individual elements may be shown in exaggerated size for better understanding.

FIG. 1 shows a schematic sectional view of an embodiment of a semiconductor emitter described herein;

FIGS. 2 to 6 show schematic sectional views of semiconductor layer sequences for embodiments of semiconductor emitters described herein;

FIG. 7 shows a schematic refractive index curve and intensity curve of an example of a semiconductor emitter described here;

FIG. 8 shows a schematic representation of a refractive index curve of a semiconductor layer sequence for embodiments of semiconductor emitters described herein;

FIG. 9 shows a schematic sectional view of a tunnel diode for embodiments of semiconductor emitters described herein;

FIG. 10 shows a schematic representation of wavelength-dependent absorption losses; and

FIGS. 11 and 12 show schematic cross-sectional views of embodiments of semiconductor emitters described herein.

### DETAILED DESCRIPTION OF ILLUSTRATIVE EMBODIMENTS

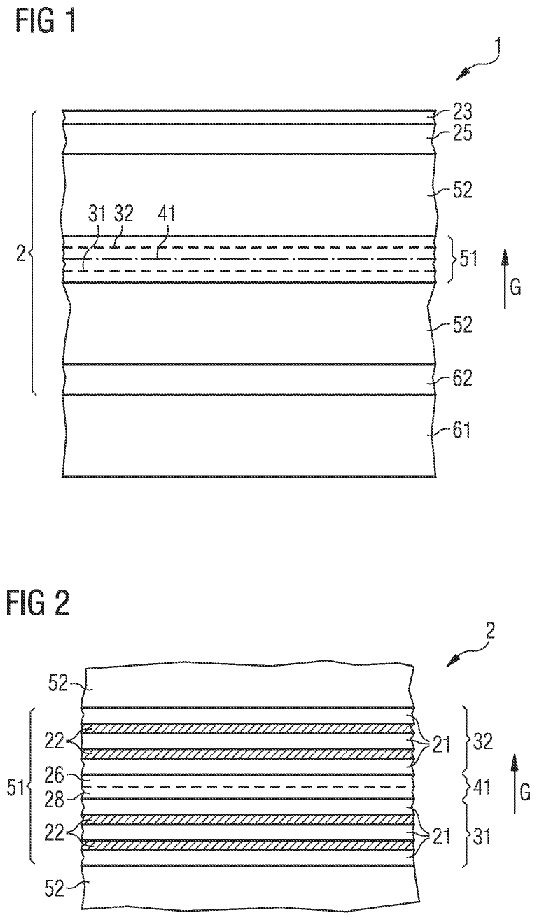

FIG. 1 shows an embodiment of a semiconductor emitter 1. The semiconductor emitter 1 comprises a semiconductor layer sequence 2 having a growth direction G and is, for example, a semiconductor laser diode. The semiconductor layer sequence 2 is located on a carrier 61. The carrier 61 may be a growth substrate of the semiconductor layer sequence 2 or a substitute carrier.

Optionally, a buffer layer 62 is located between the semiconductor layer sequence 2 and the carrier 61. The buffer layer 62 is, for example, a semiconductor layer or a bonding agent layer, such as a solder. On a side facing away from the carrier 61, the semiconductor layer sequence 2 may optionally have a contact layer 23 and/or a cap layer 25, for example, for making electrical contact with the semiconductor emitter 1. Electrical contacts or electrodes are not drawn to simplify the illustration.

Furthermore, the semiconductor layer sequence 2 comprises a waveguide 51 between two cladding layers 52. The cladding layers 52 have a lower average refractive index for radiation generated in the operation of the semiconductor emitter 1 than the waveguide 51. For example, a thickness of the cladding layers 52 is at least 1.5 times or twice a vacuum wavelength of maximum intensity of the radiation generated in the waveguide 51 divided by the average refractive index of the cladding layer 52 concerned.

Several active zones 31, 32 are present in the waveguide 51. A tunnel diode 41 is located between the active zones 31, 32. The waveguide 51 thus represents a common waveguide for all active zones 31, 32. For example, the waveguide 51 has a thickness of at least 0.3 times or 0.6 times and/or at most 1.8 times or 1.2 times or 0.9 times the vacuum wavelength of maximum intensity of the radiation generated in the waveguide 51 divided by the average or effective refractive index of the waveguide layer 51.

Various design options, in particular for the waveguide layer 51, are described below.

In the example of FIG. 2, the waveguide 51 comprises two of the active zones 31, 32, each of the active zones 31, 32 including at least two quantum well layers 22. The quantum well layers 22 are separated from each other by barrier layers 21.

A tunnel diode 41 is located between the active zones 31, 32. The tunnel diode 41 may be directly adjacent to the barrier layers 21 of the adjacent active zones 31, 32. A p-doped tunnel diode layer 26 and directly adjacent an n-doped tunnel diode layer 28 are located in the tunnel diode 41. The tunnel diode layers 26, 28 are highly doped and comparatively thin.

For example, the active zones 31, 32 are configured to generate laser radiation with a wavelength of maximum intensity in the near-infrared spectral range, that is, in particular from 0.7 μm to 1.3 μm. For example, the wavelength of maximum intensity is 940 nm. In this case, the n-doped tunnel diode layer 28 is formed, for example, from a 10 nm thick GaAs layer with a dopant concentration of 5×10¹⁹ cm⁻³, in particular of Te, alternatively also with Si and/or Ge. The p-doped tunnel diode layer 26 is, for example, a 10 nm thick GaAs layer with a dopant concentration of 1×10²⁰ cm⁻³, in particular with C, alternatively also with Be, Mg and/or Zn.

Deviating from the illustration in FIG. 2, it is also possible that the tunnel diode layers 26, 28 are asymmetrically designed and have different thicknesses. For example, the n-doped tunnel diode layer 28 is thicker than the p-doped tunnel diode layer 26 by at least a factor of 1.2 or by at least a factor of 1.5, as is also possible in all other exemplary embodiments. For example, the n-doped tunnel diode layer 28 is 15 nm thick and made of GaAs:Te with a dopant concentration of 5×10¹⁹ cm⁻³ or higher, and the p-doped tunnel diode layer 26 is 10 nm thick and made of GaAs:C with a dopant concentration of 1×10²⁰ cm⁻³ or higher, again, for example, for a laser with a maximum intensity emission wavelength of 940 nm.

Alternatively, for wavelengths of maximum intensity further in the infrared spectral range, the tunnel diode layers 26, 28 can also be made of p-doped InP and n-doped InGaAs or of p-conducting GaSb or InAs and n-conducting InAsSb. The above comments on the GaAs material system apply accordingly to the other material systems mentioned.

For example, the above thicknesses and dopant concentrations for the tunnel diode layers 26, 28 each apply with a tolerance of no more than a factor of 5 or no more than a factor of 2 or no more than a factor of 1.5.

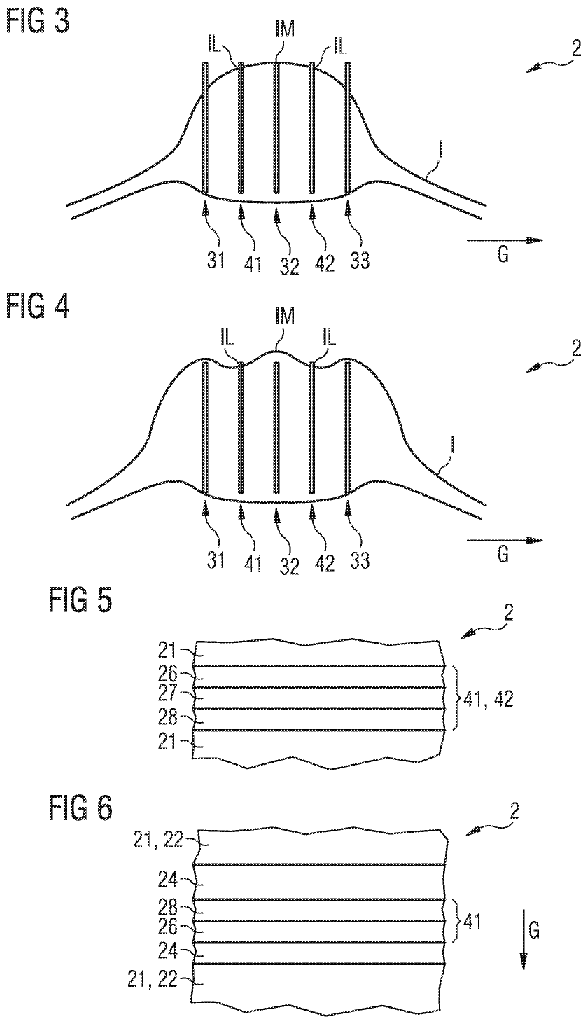

In the example of FIG. 3, it is illustrated that the waveguide 51 has three active zones 31, 32, 33 and two tunnel diodes 41, 42. The tunnel diodes 41, 42, which are located alternately between the active zones 31, 32, 33, are designed in particular as described in connection with FIG. 2.

In addition, an intensity I of an optical fundamental mode in the waveguide 51 is drawn in FIG. 3. It can be seen that the tunnel diodes 41, 42 are not in zero crossings of the intensity I, but that local intensities IL at the tunnel diodes 41, 42 are almost as high as a maximum intensity IM of the fundamental mode. This arrangement of the tunnel diodes 41, 42 is made possible in particular by the fact that the tunnel diodes 41, 42 are thin and exhibit a low absorption coefficient with respect to the radiation generated in the active zones 31, 32, 33.

In FIG. 4 it is illustrated that the fundamental mode, unlike in FIG. 3, is not Gaussian-like, but shows a slightly modulated course in the region of maximum intensity in the waveguide 51. Here, the tunnel diodes 41, 42 are in or near local minima of the intensity I, but the local intensities IL at the tunnel diodes 41, 42 are nevertheless almost as high as the maximum intensity IM of the fundamental mode.

In all other respects, the comments on FIGS. 1 and 2 apply mutatis mutandis to FIGS. 3 and 4.

FIG. 5 shows another example of tunnel diodes 41, 42. In this case, an intermediate layer 27 is located between the highly doped tunnel diode layers 26, 28. The intermediate layer 27 can also be highly doped, corresponding to the tunnel diode layers 26, 28, namely n-doped or p-doped. A thickness of the intermediate layer 27 is, for example, at least 1 nm or at least 3 nm and/or at most 20 nm or at most 15 nm.

In the case of tunnel diode layers 26, 28 made of GaAs, the intermediate layer 27 is preferably made of InAs or InGaAs with, for example, an In content of at most 80% or at most 50% or at most 30% or at most 10%, although AlInGaAs layers with an Al content of, in particular, at most 30% or at most 10% or at most 1% and with an In content of at most 30% or of at most 10% are also possible.

Such tunnel diodes 41, 42 may also be used in all other embodiments.

In all other respects, the comments on FIGS. 1 to 4 apply accordingly to FIG. 5.

In the embodiment example of FIG. 6, at least one transition layer 24 is adjacent to the tunnel diode 41. If two transition layers 24 are present, the transition layer 24 at the n-doped tunnel diode layer 28 may be thicker than the p-side transition layer 24, for example, by a factor of at least 1.5 and/or by a factor of at most 4. A thickness of the thinner transition layer 24 is in particular at least 2 nm or at least 5 nm and/or at most 30 nm or at most 20 nm.

In the case of a GaAs-based tunnel diode 41, the transition layers 24 are preferably each made of AlGaAs, with an Al content towards the tunnel diode 41 preferably reducing steadily, in particular linearly. For example, an Al content on sides of the transition layers 24 facing away from the tunnel diode 24 is at least 5% and/or at most 30%, for example 14%, and on sides of the transition layers 24 facing the tunnel diode 24 the Al content is at most 20% or at most 5% or at most 0.5%, in particular 0%.

Such transition layers 24 may also be present in all other embodiments.

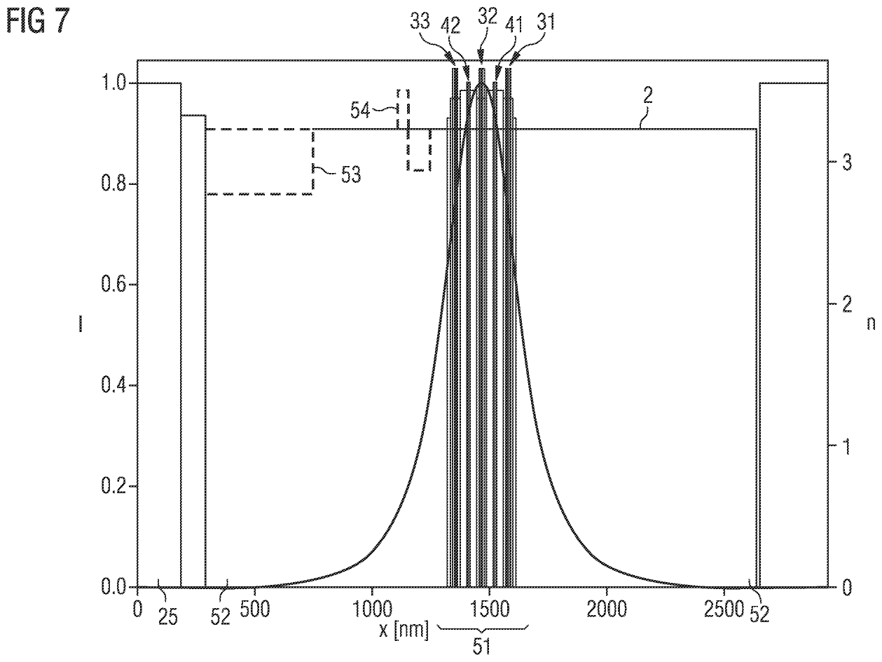

In FIG. 7 the intensity I of the fundamental mode in the semiconductor layer sequence 2 is illustrated, as well as the refractive index n. The semiconductor layer sequence 2 is based in particular on the material system AlInGaAs. In the waveguide 51, the active zones 31, 32, 33 and also the tunnel diodes 41, 42 have a relatively high refractive index. Thus, the tunnel diodes 41, 42 can contribute to waveguiding and increase the effective refractive index of the waveguide 51.

Furthermore, it can be seen in FIG. 7 that the fundamental mode is Gaussian-like. Thus, a high quality emission of the laser radiation is possible.

As an option, it is illustrated in FIG. 7 that one or both cladding layers 52 may have a decreasing refractive index in the direction away from the waveguide 51. For example, at least one step 53 is present in the refractive index curve, symbolized as a dash line. Alternatively, there may be a continuous refractive index decrease, not drawn.

As a further option, it is shown in FIG. 7 that the cladding layers 52 may also include at least one substructure 54, illustrated as a dash-dot line. The substructure 54 comprises, for example, a local refractive index increase optionally associated with an adjacent region of locally reduced refractive index.

In all other respects, the comments on FIGS. 1 to 6 apply accordingly to FIG. 7.

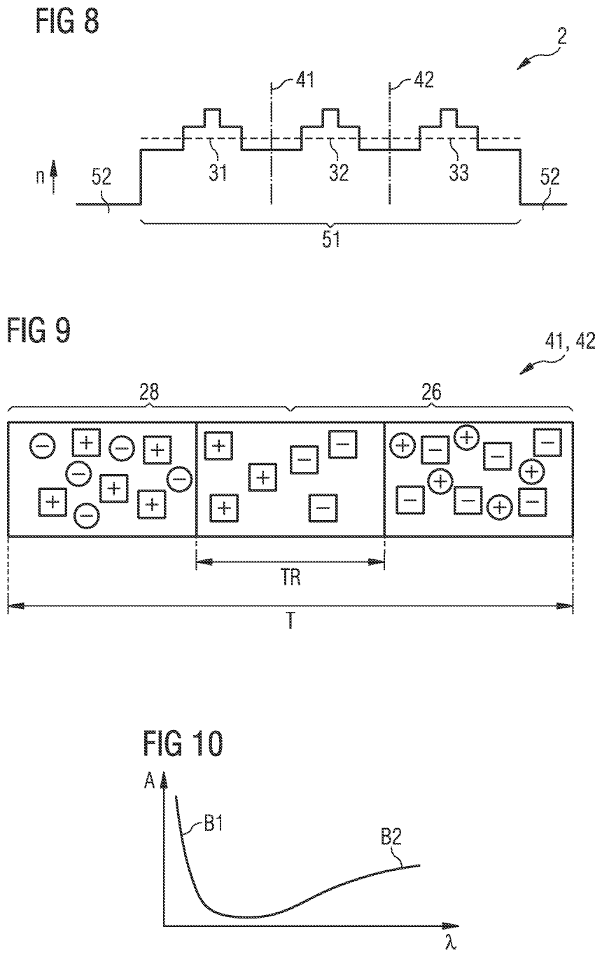

According to FIG. 8, the waveguide 51 is more structured with respect to the refractive index profile than in FIG. 7. Thus, the active zones 31, 32, 33 can each comprise weakly pronounced sub-waveguides of their own. A resulting effective refractive index is drawn as a dashed line.

With such a structure of the waveguide 51, intensity curves can be obtained which show a wavy course in the region of maximum intensity, as illustrated in FIG. 4.

In all other respects, the comments on FIGS. 1 to 7 apply mutatis mutandis to FIG. 8.

FIG. 9 illustrates an example of a space charge region 44 of the tunnel diode 41, 42. A thickness TR of the space charge region 44 is one third or more of a total thickness T of the tunnel diode 41, 42, that is, the space charge region 44 makes up a considerable portion of the tunnel diode 41, 42.

In this context, areas B1, B2 of the wavelength-dependent absorption A are schematically illustrated in FIG. 10. In region B1, absorption is predominantly due to fundamental absorption of the semiconductor material concerned. In contrast, absorption in region B2 is essentially based on the presence of free charge carriers.

Since in the tunnel diode 41, 42, as shown in particular in FIG. 9, the space charge region 44, which is essentially free of free charge carriers, accounts for a high proportion of the total thickness T of the tunnel diode 41, 42, the absorption due to free charge carriers can be minimized. In addition, absorption due to fundamental absorption can be virtually eliminated by the choice of material or by the choice of band gap for the tunnel diode 41, 42.

Thus, the tunnel diodes 41, 42 described herein have an overall low absorption coefficient for the generated radiation, so that the tunnel diodes 41, 42 can be placed in the common waveguide 51 in regions of high local intensity IL to improve the radiation pattern.

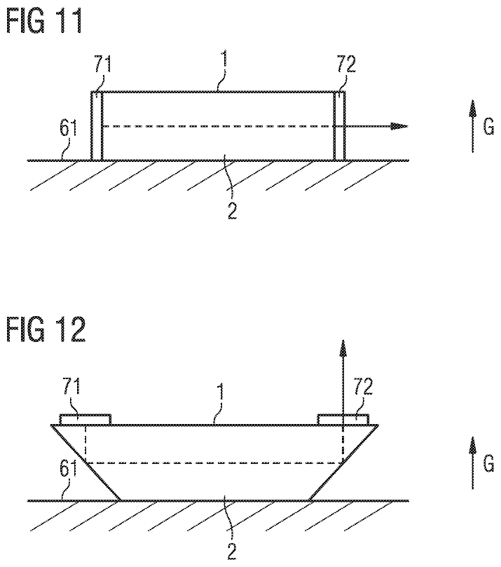

FIGS. 11 and 12 further illustrate embodiments of the semiconductor emitter 1. According to FIG. 11, the semiconductor layer sequence has a highly reflective resonator end mirror 71 on opposite facets as well as an outcoupling coating 72 with a reflectivity adapted to a required feedback back into the resonator. The facets are oriented parallel to the growth direction G.

In contrast, the facets according to FIG. 12 are oriented approximately at a 45° angle to the growth direction G. This allows the highly reflective resonator end mirror 71 and the outcoupling coating 72 to be applied to a surface of the semiconductor layer sequence 2. This design is also referred to as a horizontal cavity surface emitting laser, or HCSEL.

The semiconductor layer sequences 2 and in particular the tunnel diodes 41, 42 described in connection with FIGS. 1 to 10 can be used in all of the semiconductor emitters 1 according to FIGS. 11 and 12.

The invention described herein is not limited by the description based on the embodiments. Rather, the invention encompasses any new feature as well as any combination of features, which in particular includes any combination of features in the patent claims, even if this feature or combination itself is not explicitly stated in the patent claims or embodiments.

1-15. (canceled)

16. A semiconductor emitter comprising:
a semiconductor layer sequence comprising:
a plurality of active zones, each active zone including at least one quantum well layer and at least two barrier layers between which the at least one quantum well layer is embedded; and
at least one tunnel diode located along a growth direction of the semiconductor layer sequence between adjacent active zones,
wherein a thickness of the at least one tunnel diode is at most 40 nm,
wherein, when in operation, a local intensity of a fundamental optical mode at the at least one tunnel diode is at least 50% of a maximum intensity, and
wherein a distance between adjacent barrier layers of adjacent active zones, facing the at least one tunnel diode, is at most 50 nm.

17. The semiconductor emitter according to claim 16, wherein the active zones and the at least one tunnel diode are located in a common waveguide of the semiconductor layer sequence.

18. The semiconductor emitter according to claim 17, wherein a thickness of the common waveguide together with associated cladding layers is at most 4 μm.

19. The semiconductor emitter according to claim 18, wherein at least one of the cladding layers comprises a stepped progression such that a refractive index of a respective cladding layer decreases in a direction away from the active zones with at least one step.

20. The semiconductor emitter according to claim 16, wherein a thickness of a space charge region is at least 30% of a total thickness of the at least one tunnel diode.

21. The semiconductor emitter according to claim 16, wherein a wavelength corresponding to a bandgap of the at least one tunnel diode is smaller by at least 30 nm than a wavelength of maximum intensity of a radiation generatable in the active zones.

22. The semiconductor emitter according to claim 16, wherein the at least one tunnel diode is formed of two oppositely highly doped layers, each having a thickness of at most 20 nm.

23. The semiconductor emitter according to claim 16, wherein the at least one tunnel diode is formed of two oppositely highly doped layers, each having a thickness of at most 15 nm, and of at least one intervening intermediate layer having a thickness of at most 15 nm.

24. The semiconductor emitter according to claim 16, wherein the semiconductor layer sequence further comprises at least one low-doped transition layer adjacent to the at least one tunnel diode, and wherein the at least one transition layer has a ramped refractive index profile with a refractive index increasing in a direction towards the at least one tunnel diode.

25. The semiconductor emitter according to claim 16, wherein the at least one tunnel diode comprises GaAs and/or InGaAs.

26. The semiconductor emitter according to claim 16, wherein the at least one tunnel diode comprises InP and InGaAs or InAsSb and GaSb.

27. The semiconductor emitter according to claim 16,
wherein an average dopant concentration in the at least one tunnel diode is between 2×1019 cm-3 and 2×1020 cm-3, inclusive, and
wherein a dopant concentration of layers of the semiconductor layer sequence adjacent to the at least one tunnel diode is smaller than the average dopant concentration in the at least one tunnel diode by at least a factor of three.

28. The semiconductor emitter according to claim 16, wherein an optical fundamental mode exhibits a plurality of local maxima and at least one local minimum, and
wherein the active zones are located in the local maxima and the at least one tunnel diode is located in the at least one local minimum.

29. The semiconductor emitter according to claim 16, wherein at least two of the active zones is configured to generate radiation of different wavelengths.

30. The semiconductor emitter according to claim 16,
wherein the semiconductor layer sequence comprises at least three of the active zones,
wherein each of the active zones includes between two and ten, inclusive, of the quantum well layers, and
wherein the semiconductor emitter is a semiconductor laser.

31. A semiconductor emitter comprising:
a semiconductor layer sequence comprising:
a plurality of active zones, each zone including at least one quantum well layer and at least two barrier layers between which the at least one quantum well layer is directly embedded; and
at least one tunnel diode located along a growth direction of the semiconductor layer sequence between adjacent active zones,
wherein a thickness of the at least one tunnel diode is at most 40 nm,
wherein, when in operation, a fundamental optical mode at the at least one tunnel diode is at least 50% of a maximum intensity,
wherein a distance between adjacent barrier layers of adjacent active zones, facing the at least one tunnel diode, is at most 50 nm, and
wherein either the at least one tunnel diode consists of two oppositely highly doped layers, each having a thickness of at most 20 nm, or
wherein the at least one tunnel diode consists of two oppositely highly doped layers, each having a thickness of at most 15 nm, and of at least one intervening intermediate layer having a thickness of at most 15 nm.
